(19) United States
(12) Patent Application Publication
(10) Pub. No.: US 2025/0321287 A1
(43) Pub. Date: Oct. 16, 2025

(54) METHOD AND SYSTEM FOR EARLY DETECTION OF CRITICAL BATTERY FAULTS

(71) Applicant: ACCURE BATTERY INTELLIGENCE GMBH, Aachen (DE)

(72) Inventors: Kai-Philipp Kairies, Aachen (DE); Georg Angenendt, Aachen (DE)

(73) Assignee: ACCURE BATTERY INTELLIGENCE GMBH, Aachen (DE)

(21) Appl. No.: 18/876,038

(22) PCT Filed: May 15, 2023
(86) PCT No.: PCT/EP2023/062999

§ 371 Date: Dec. 17, 2024

(30) Foreign Application Priority Data
Jun. 24, 2022 (DE) 102022115777.6

(51) Int. Cl. G01R 31/392; G01R 31/367; G01R 31/371; G01R 31/3842; G01R 31/389

(52) U.S. Cl. CPC G01R 31/392; G01R 31/367; G01R 31/371; G01R 31/3842; G01R 31/389

(57) ABSTRACT

A method for early detection of critical faults of a battery (4, 5, 6), after commissioning and during battery operation of the battery (4, 5, 6), comprises receiving battery data provided by a battery management system, BMS (2), associated with the battery (4, 5, 6), at a remote diagnostic unit (3), the battery data relating in time to electrical characteristics of the battery (4, 5, 6) measured during battery operation; and performing a remote diagnosis of the battery (4, 5, 6) by comparing the received battery data with reference battery data phase by phase and/or cycle by cycle, wherein a phase is one of: a charging phase, a transition phase and a discharging phase in relation to the battery operation, and wherein a cycle comprises successive phases of the charging phase, the transition phase and the discharging phase.

### TECHNICAL AREA

The invention relates to a method having the features of the preamble in claim 1 and to a system for the early detection of critical faults in a battery.

The following background is merely intended to provide information necessary to understand the context of the inventive ideas and concepts disclosed herein. Therefore, this background section may include patentable subject-matter and should not be considered prior art per se.

### BACKGROUND

For lithium-ion battery storage systems, especially for electrically powered vehicles, there is a trend towards the development of high-performance battery packs with associated battery management systems (BMS), i.e. electronic control units equipped with software for monitoring battery functionality and measuring electrical characteristics/properties. Among other things, battery management systems ensure the safe and reliable functioning of the battery cells and battery packs used. They monitor, measure and control currents, voltages, temperatures, insulation resistances and other electrical characteristics or properties for individual battery cells, battery modules and/or battery packs. These variables can be used to implement management functions that increase the service life, reliability and safety of the battery system.

There are various architectures for measuring the battery cells grouped into the battery modules, the battery modules grouped into the battery pack and/or the battery pack itself.

One possibility is to provide each battery cell or battery module with a sensor control unit that communicates with a main control unit common to the sensor control units, for example via a Controller Area Network (CAN) bus or Serial Peripheral Interface (SPI) bus. These sensor control units, for example, cyclically measure values in the form of electrical characteristics/properties, such as temperature, current or voltages, of the individual battery cells or a battery string (parallel connection of the battery cells). The measured values are communicated cyclically to the main control unit so that one sensor control unit after the other provides the measured values of the associated battery cells. The measurement and provision can take place periodically so that, for example, one cell of each battery module is measured per period and the corresponding measured values are transmitted cyclically in the corresponding period. The number of periods can therefore correspond to the number of battery cells per battery module. A period can also correspond to the cyclical processing of the measurements on a battery module, whereby the number of periods would correspond to the number of battery modules per battery pack.

With the increasing demand for battery storage, especially in electrically powered vehicles, and the already highly developed BMS, unforeseen fires are becoming more frequent, especially in stationary and automotive environments.

The invention is therefore based on the problem of avoiding the danger of battery fires.

### BRIEF SUMMARY

The purpose of this brief summary is to present a selection of features and concepts of the invention, which are explained further below in the description. This brief summary is not intended to identify important or essential features of the claimed subject-matter, nor is it intended to limit the scope of the claimed subject-matter.

According to the invention, the above problem is solved by the features of the independent claims.

Specifically, the problem is solved by a method for early detection of critical faults in a battery. The method is performed after commissioning and preferably during battery operation of the battery. The method comprises receiving battery data at a remote diagnostic unit. The battery data is provided by a battery management system (BMS) associated with the battery. The battery data relates temporally to electrical characteristics/properties of the battery. The electrical characteristics/properties are measured during battery operation. The method comprises performing a remote diagnosis of the battery by comparing the received battery data with reference battery data on a phase-by-phase and/or cycle-by-cycle basis. A phase is (e.g. exactly) one of: a charging phase, a transition phase and a discharging phase related to the battery operation. A cycle comprises (e.g. once) successive phases of the charging phase, the transition phase and the discharging phase.

The invention has the advantage that battery fires can be avoided.

The electrical characteristics/properties may comprise at least current, voltage and/or temperature. For example, the battery data relates the current through the battery to the terminal voltage of the battery over time. Current and voltage can therefore be resolved over time (time resolution) in the received battery data. It should be clear to a skilled person that outliers in the raw data of the measured electrical characteristics/properties can be omitted by a pre-processing step, which can be performed during the battery data reception step or directly subsequent to it, and the remote diagnosis is then performed on the pre-processed battery data. Corresponding outliers can also be recognized as non-critical or critical errors, e.g. sensor errors, during pre-processing.

The battery referred to herein may be a cell, a module, a pack, or a battery system, in particular a battery cell/battery module/battery pack/battery system from a batch of a plurality of battery cells/battery modules/battery packs/battery systems that has undergone the same battery formation process at the same time.

The temporal relationship of the electrical characteristics/properties can be time-resolved. The phase-wise comparing can be a comparison performed per phase of the time-resolved battery data. The cycle-by-cycle comparison may be a comparison performed per cycle of the time-resolved collected data. In particular, a cycle may comprise all phases (e.g. exactly) once.

For example, battery data can be received incrementally (step-wise), and remote diagnosis can be performed incrementally (step-wise) on it or on a batch from the incrementally (step-wise) received battery data.

Situational adaptation can be improved by taking the time component into account.

Advantageous embodiments of the invention are set out in the dependent claims.

The transition phase can lie between the charging phase and the discharging phase, the charging phase to another charging phase, the discharging phase to another discharging phase and/or from the discharging phase to the charging phase. The term “transition phase” can be understood as a transition in which an edge, in particular a current edge, voltage edge and/or temperature edge, is steep in the time resolution. The current slope can be greater than 0.01 (0.05, 0.1, 0.5, 1 or 10) A/s. The voltage slope can be greater than 0.1 (0.5, 1, 5, 10 or 100) V/s. The temperature slope can be greater than 0.01 (or 0.05) K/s and/or less than 1 (or 0.5) K/s. However, it is understood that the transition phase may be a monotonic function, but may also have a rest phase between the transition phases, such as a plateau. The rest phase may be shorter (in time) than the entire transition phase, or shorter than ⅓, ⅕, ⅛ or 1/10 of the entire transition slope. The diagnostic capability can thus be increased.

The reference battery data can be battery data that originates from a historical battery data set. For example, the battery data may be from a plurality of similar battery batches and/or the same battery batch. The reference battery data may be collected from at least one battery batch, or may include such data. The at least one or more battery batches may be a different battery batch or a plurality of different battery batches than the battery batch to which the (current) battery belongs. Furthermore, the at least one battery batch may be a historical battery batch or several different historical battery batches. Alternatively or additionally, the reference battery data may be or include data from a current battery data set of a same batch to which the (current) battery belongs. Thus, in one example, the reference battery data may be based on the (current) battery.

Such data fusion can guarantee the quality of the process.

The method may further comprise extracting one or more functional profiles from the (incrementally) received battery data. Performing the remote diagnosis may further comprise comparing the one or more functional profiles of the received battery data with corresponding one or more functional profiles of the reference battery data.

This enables a simple function-related comparison to reduce the effort required for quality analysis.

Performing the remote diagnosis may further comprise triggering one or more indicators when one or more differences between the one or more functional profiles of the received battery data and the corresponding one or more functional profiles of the reference battery data exceed corresponding one or more predetermined thresholds. The one or more indicators may be a quality indicator indicating that the battery is defective or has a quality defect. For a more reliable result, the multiple indicators can be used to indicate that the battery is defective or has a quality defect. In this case, several threshold values can be exceeded, triggering several indicators.

The indicators can be simple flag(s) that indicate errors in the battery. One or more flags, e.g. more than three flags, can indicate an error.

This allows the battery to be indexed and removed if the opportunity arises. This possibility can also be communicated to other users of batteries of the same batch in order to anticipate and prevent fires that may similarly occur in the entire batch. Further, the threshold can be a nominal or normalized value in a range between 0.05 and 0.3 or 0.1 and 0.2.

The battery data or the one or more functional profiles may comprise derivatives of a charge of the battery with respect to a terminal voltage of the battery according to the respective charging phases and discharging phases. The battery data or the one or more functional profiles may comprise derivatives of the terminal voltage of the battery with respect to the charge of the battery according to the respective charging phases and discharging phases. The battery data or the one or more functional profiles may comprise charge and/or energy throughputs according to the respective charging phases and discharging phases. The battery data or the one or more functional profiles may comprise internal resistances according to the respective transition phases. The battery data or the one or more functional profiles may comprise electrical circuit models according to the respective transition phases and/or the electrical circuit models according to the respective charging phases and/or discharging phases. The battery data or the one or more functional profiles may comprise Coulomb and/or energy and/or voltaic efficiencies and/or capacities or changes thereto according to the respective cycles.

Consequently, a diagnosis of several categories can be performed as a quality test during remote diagnosis.

The remote diagnosis may be performed by comparing at least one maximum and/or at least one minimum of the derivatives with at least one maximum and/or at least one minimum of derivatives in the reference battery data. The remote diagnosis can be performed by comparing each of the derivatives with corresponding statistical upper and lower limit curves associated with the derivatives in the reference battery data. The remote diagnosis can be performed by comparing the charge and/or energy throughputs with at least one first statistical boundary condition of the reference battery data. The remote diagnosis can be performed by comparing the internal resistances with at least one second statistical boundary condition of the reference battery data.

The remote diagnosis may be performed by adapting parameters of the electrical circuit models to the battery data or the one or more functional profiles, and additionally: respectively comparing the parameters of the electrical circuit models with corresponding parameters of an equivalent electrical circuit model of the reference battery data and/or respectively comparing the parameters of the electrical circuit models with at least one third statistical boundary condition associated with the corresponding parameters of the reference battery data. One of the electrical circuit models may be a series connection of a voltage source, a first resistor and a parallel connection of a second resistor and a capacitor, from one voltage terminal of the battery to the other voltage terminal of the battery. Another electrical circuit model may be a series connection of a third resistor and a Warburg impedance, from one voltage terminal of the battery to the other voltage terminal of the battery. The parameters described herein can be understood as values of the respective circuit elements of the electrical circuit model used.

This ensures an appropriate Q-factor.

The remote diagnosis can be performed by comparing the Coulomb and/or energy and/or voltaic efficiencies with at least one fourth statistical boundary condition of the reference battery data.

The remote diagnosis can be performed by comparing the capacities or changes to them with at least one fifth statistical boundary condition of the reference battery data.

The at least one first, second, third, fourth and fifth statistical boundary condition can be independent of one another. For example, the at least one first, second, third, fourth and fifth statistical boundary condition may be different from one another. The at least one first, second, third, fourth and fifth statistical boundary condition may correspond to a respective envelope of a statistical distribution of values of the reference battery data, such as a normal distribution or a Gaussian distribution. The at least one first, second, third, fourth and fifth statistical boundary condition may each be a set of boundary conditions. The set of boundary conditions can be checked one after the other, e.g. depending on whether a previous boundary condition is fulfilled or not. The sequence within the set can be arbitrary, e.g. irregular or random, or deterministic.

Consequently, data fusion of some or all of these techniques can provide a better quality of remote diagnosis. A result can also be achieved more quickly.

The above problem is also solved by a computer program. The computer program comprises instructions which, when the computer program is executed by a computer or by a BMS, an arbiter and/or a remote diagnostic unit, cause the computer or the BMS, the arbiter and/or the remote diagnostic unit to perform the method described above or at least one of the steps thereof. The computer program may be, for example, a module for starting/operating the BMS, the arbiter and/or the remote diagnostic unit. The computer program may be stored on a machine-readable storage medium, such as a permanent or rewritable storage medium. Additionally or alternatively, the computer program may be provided on a server or a cloud server for downloading, for example via a data network such as the Internet or a communication link such as a wireless connection.

The above problem is also solved by a computer-readable data carrier. The computer program described above is stored on the computer-readable data carrier.

The above problem is also solved by a system for the early detection of critical faults in a battery. This is preferably done after commissioning and during battery operation of the battery. The system comprises a battery management system (BMS) associated with the battery. The BMS is adapted to provide battery data. The battery data relates to electrical characteristics of the battery measured during battery operation. The system comprises a remote diagnostic unit. The remote diagnostic unit is adapted to perform a remote diagnosis of the battery by comparing the battery data received phase by phase and/or cycle by cycle with reference battery data. A phase is (e.g. exactly) one of: a charging phase, a transition phase and a discharging phase in relation to battery operation. A cycle comprises (e.g. exactly once) successive phases of the charging phase, the transition phase and the discharging phase.

The BMS can provide the battery data in partial batches, for example, which are combined into a complete batch by the remote diagnostic unit. This can be useful, for example, during a handover between mobile radio cells.

The system or the BMS can include a gateway for transmitting the battery data to the remote diagnostic unit. In one example, an arbiter can be connected between the BMS and the remote diagnostic unit as part of the system. The arbiter can be understood here as an intermediary between the BMS and the remote diagnostic unit and can preferably have memory technology that enables the battery data to be retained. In this way, the data transfer from the BMS to the remote diagnostic unit and vice versa can be initiated and controlled via another control instance, the arbiter. In this way, all communication can be operated via the arbiter. Direct data transfer can also be provided. The remote diagnostic unit can be part of an onsite or remote cloud system. This can provide a remote diagnostic unit that can be designed independently of the BMS and arbiter, thus increasing the degree of freedom.

In other words, the invention relates to the early detection of critical battery faults such as fires. Applications include, for example, electric cars, stationary energy storage systems or consumer electronics. The method can provide for this: Analyzing battery data during operation. In further words, the process can be as follows: The battery management system (BMS) of the battery measures current, voltage and temperature; forwards this data measured in this way via the communication bus (e.g. CAN), whereby the CAN signals are pushed from a data logger to the cloud-either directly or at (in) regular intervals. The data is then analyzed in the cloud and warnings are issued if batteries are classified as safety-critical. Corresponding safety measures can then be taken.

The term “battery” is used herein for accumulator, adapted to common usage. The battery comprises one or more battery units, which may refer to a battery cell, a battery module, a module string or a battery pack. In the battery, the battery cells are preferably physically abstracted and connected to each other in a circuit, for example connected in series or parallel to form battery modules. Several battery modules can form so-called battery direct converters (BDC, Battery Direct Converter) and several battery direct converters can form a battery direct inverter (BDI, Battery Direct Inverter). In particular, the battery can be a lithium-ion battery or a nickel-metal hydride battery and be adapted to be connected to a drive system of a motor vehicle.

The above problem can also be solved by a battery management system (BMS) per se, a motor vehicle with the BMS or a fleet of motor vehicles with respective BMS as described above. The details are omitted here for the sake of clarity. It is understood that the aspects described above may apply with respect to the method, the system, the BMS, the motor vehicle or the motor vehicle fleet. In the same way, the aspects described above in relation to the system, the BMS, the motor vehicle or the fleet of motor vehicles may apply to the method in a corresponding manner.

For example, the motor vehicle can be provided with the BMS and the battery as described above. The battery may be connected to a drive system of the motor vehicle. The motor vehicle may be designed as a pure electric vehicle and comprise an electric drive system only. Alternatively, the motor vehicle may be a hybrid vehicle comprising an electric drive system and an internal combustion engine. It may further be provided that the battery of the hybrid vehicle can be charged internally via a generator using excess energy from the combustion engine. Externally rechargeable hybrid vehicles (PHEV, Plug-in Hybrid Electric Vehicle) also provide for the possibility of charging the battery via an external power grid. In such vehicles, the driving cycle comprises a driving mode and/or a charging mode as operating phases in which operating parameters such as the above-mentioned electrical characteristics/properties are recorded.

It will be understood by the skilled person that the explanations set forth herein may be implemented using hardware circuitry, software means, or a combination thereof. The software means may be related to programmed microprocessors, application specific integrated circuits (ASICs) and/or digital signal processors (DSPs). The units of the BMS, the arbiter and the remote diagnostic unit are each to be understood as functional units that are not necessarily physically separated from each other. Thus, several units of the BMS, the arbiter and the remote diagnostic unit can each be realized in a single physical unit, for example if several functions are implemented in software. The units of the BMS, the arbiter and the remote diagnostic unit can also be implemented in hardware components.

In one example, the BMS, the arbiter, and the remote diagnostic unit may be at least partially implemented as a computer, logic circuit, field programmable logic gate array (FPGA), microprocessor, microcontroller, vector processor, processor integrated core, CPU (e.g., multi-core), coprocessor (microprocessor supporting the CPU), graphics processing unit (GPU), and/or DSP.

In the BMS, the arbiter and/or the remote diagnostic unit, for example, methods can be used that are associated with pipelining the battery data. In this case, instead of an entire command being processed in one clock cycle of the processor used in the BMS, the arbiter and/or the remote diagnostic unit, only a subtask of it, e.g. part of the battery data, is processed. The various subtasks of several commands are processed simultaneously. Further, methods in the sense of multithreading can be applied to the battery data and further developments thereof, for example simultaneous multithreading of the battery data. This makes it possible to achieve better processor utilization due to the parallel use of several processor cores. The processor included in the BMS, the arbiter and/or the remote diagnostic unit can be connected to a buffer memory that can temporarily store the battery data before and/or after processing the battery data or part thereof. The buffer memory can be integrated in a volatile memory, e.g. a (D) RAM, or in a persistent storage, e.g. a non-volatile memory device such as an SSD. This can increase performance.

Unless otherwise defined, all technical and scientific terms used herein have the meaning that corresponds to the general understanding of the skilled person in the field of battery and energy storage technology relevant to the present disclosure; they are to be defined neither too broadly nor too narrowly. If technical terms are used incorrectly in the present disclosure and thus do not express the technical idea of the present disclosure, they are to be replaced by technical terms that convey a correct understanding to the skilled person. The general terms used in the present disclosure are to be interpreted on the basis of the definition found in the dictionary or corresponding to the technical jargon.

Although terms such as “first” or “second” etc. may be used to describe different components, these components are not to be limited to these terms. The above terms are merely intended to distinguish one component from another. For example, a first component may be referred to as a second component and a second component may be referred to as a first component.

If a component is “connected to” or “communicates with” another component, this can mean that it is directly connected to or communicates with it; however, it should be noted that there may be another component in between. On the other hand, if it is said that a component is “directly connected” to another component or “communicates directly” with it, it is to be understood that there are no other components in between.

The method steps described herein should not be construed herein as having to be performed in any particular order, unless expressly or implicitly indicated otherwise, for example if these method steps cannot be interchanged for technical reasons. Also, the method steps described herein may be performed directly, sequentially, consecutively and/or successively. However, there may also be other process steps in between.

### BRIEF DESCRIPTION OF THE DRAWINGS

Further objectives, features, advantages and possible applications are apparent from the following description of embodiments, which are not to be understood as limiting, with reference to the associated drawings. The same or similar elements in the drawings are always provided with the same or similar reference numbers. Detailed explanations of known functions and structures are omitted insofar as they detract from the invention.

The drawings show in:

FIG. 1 a view of a system for the early detection of critical faults in a battery;

FIG. 2 a view of a method for early detection of critical faults of a battery; and

FIG. 3 a view of a computer used in parts of the system and method for early detection of critical faults in a battery.

### DETAILED DESCRIPTION

The system 1 for early detection of critical faults of a battery and the method S20 therefor, as well as the computer used therein, will now be described with reference to the embodiments. Without being limited to this, specific details are explained in order to provide a deeper understanding of the invention.

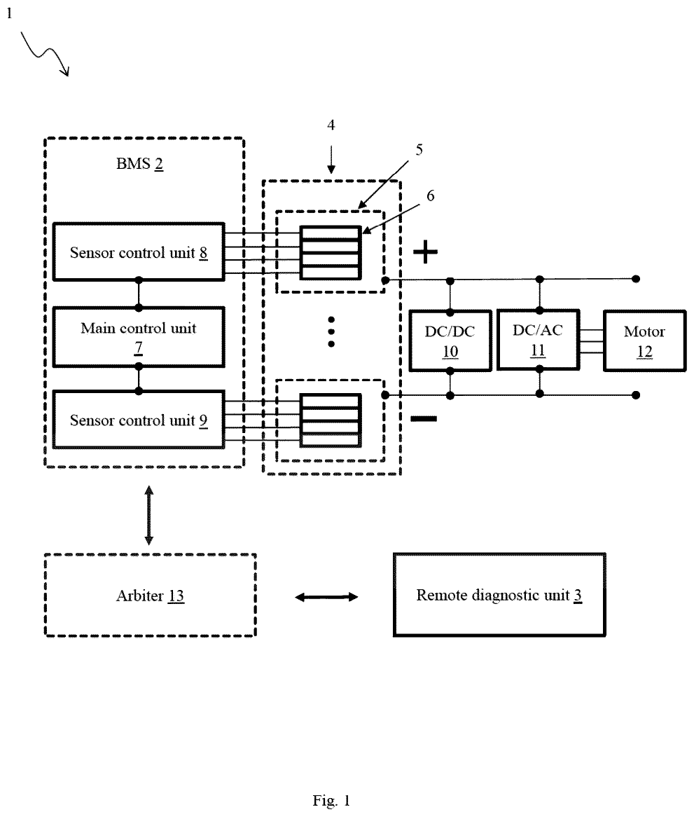

FIG. 1 shows a system 1 for the early detection of critical faults in a battery 4, in particular a vehicle battery. The system 1 comprises a battery management system (BMS) 2—in particular a vehicle BMS—with a main control unit 7, which can also be referred to as a battery control unit (BCU), and sensor control units 8 and 9, a battery 4 with a number of battery modules 5, which includes individual grouped battery cells 6. Each battery module 5 is assigned its own sensor control unit 8, 9. The main control unit 7 implements functions for controlling, monitoring and measuring the battery 4. The system 1 can be understood as a vehicle management system or vehicle fleet management system, since the system 1 can be designed for the same battery 4 type or vehicle class.

The BMS 2 ensures the safe and reliable functioning of the battery cells 6, the battery modules 5 and the battery 4 or the battery pack. The BMS 2 monitors and controls currents, voltages, temperatures, insulation resistance and other variables for the battery cells 6 or the battery 4 or the entire battery pack. In addition to management functions, these variables can also be used to implement the remote diagnostic function as envisaged here, which increases the service life, reliability and safety when using the battery 4. The BMS 2 consists of a plurality of control units, such as the main control unit 7 and the sensor control units 8, 9, on which individual software functionalities run.

Depending on the number of battery cells 6, the number of sensors and the distribution of the battery modules 5 to different installation spaces in the vehicle, a control unit topology with a main control unit 7 and several subordinate sensor control units 8, 9 for recording the data to be measured directly on the individual battery modules 5 is created. The data to be measured, also referred to herein as electrical characteristics/properties, can be voltages, temperatures, currents, etc., for example. The measured data is exchanged between the control units via a communication bus, for example a Controller Area Network (CAN). The BMS 2 or its elements 7, 8, 9 can be interconnected via the communication bus in order to collect the electrical characteristics/properties recorded by various sensors, such as current, voltage and temperature.

The sensor control units 8, 9 of a measurement chain (e.g. a series of battery cells 6 corresponding to several battery modules 5) and the main control unit 7 are connected to each other, for example, in a daisy chain in series to the communication bus. It is particularly preferred that the measurement chains are each connected serially to the communication bus via a daisy chain. The measured data is recorded and processed by the main control unit 7 via the communication bus, for example in the form of an SPI communication bus.

In this example, four battery cells 6 are assigned to each battery module 5, whereby these can be connected in series and in some cases also in parallel in order to meet the required power and energy requirements of the battery 4. The battery 4 provides the electrical energy at battery connections (+, −), for example to drive a vehicle. The battery 4 can supply energy to load(s) connected to these battery connections (+, −), for example high-voltage parts connected via rectifiers (DC/DC 10) and/or inverters (DC/AC 11). Here, a motor 12 or an air conditioner (not shown) can be connected to the DC/AC 11 by means of a three-phase cable. For example, the DC/DC converter 10 can be provided for an on-board electrical system (of the vehicle) and loads connected to it, and the DC/AC converter 11 can be provided to supply the electric drive (motor 12) with the necessary energy during operation. Other loads that can be supplied with energy by the battery 4 are electronic elements within the vehicle associated with the BMS 2, such as a low-voltage DC/DC converter (LDC) (not shown).

A cathode and an anode of the battery 4 (battery terminals (+, −)) can be connected to or disconnected (e.g. switched off) from corresponding two terminals of the load(s) depending on a controller of the BMS 2. Other load(s) may be various drive loads, such as a hybrid starter-generator (HSG) motor supplied with power via the three-phase cable connected to the DC/AC 11, which is another high-voltage part configured to support starting, a full automatic temperature control system (FATC), a hybrid starter-generator (HSG) motor connected to the DC/AC 11, a hybrid starter-generator (HSG) motor connected to the DC/AC 11, a hybrid starter-generator (HSG) motor connected to the DC/AC 11, and configured to support starting, a full automatic temperature control system (FATC), a hybrid starter-generator (HSG) motor, a hybrid starter-generator (HSG) motor, a hybrid starter-generator (HSG) motor, a hybrid starter-generator (HSG) motor full automatic temperature control system), a positive temperature coefficient (PTC) heater, and an on-board charger (OBC) connected to the battery 4 via a relay controlled by the BMS 2 to support charging of the battery 21.

Communication between the main control unit 7 and the sensor control units 8, 9 takes place via a communication channel and adapted interfaces (represented schematically as a line with end points in FIG. 1).

The sensor control units 8, 9 control battery cell monitoring units or battery module monitoring units, which continuously, periodically and/or cyclically, with predetermined or adaptable sampling rates, record operating parameters, also referred to herein as electrical characteristics/properties, such as voltages, currents or temperatures of individual battery cells 6 or individual battery modules 5 as measured values and provide the recorded measured values to the sensor control units 8, 9. The sensor control units 8, 9 are connected to the battery cells 6 via measuring lines (see solid lines).

The main control unit 7 requests the measured values of the electrical characteristics/properties recorded by the sensor control units via the communication channel. This request can be made automatically or at predetermined time intervals. For example, a request interval during an operation of the battery 4 may be shorter than a request interval outside the operation of the battery 4, e.g. when no energy is provided by the battery 4. The same may apply to a measurement interval related to the measurements by the sensor control units 8, 9.

The main control unit 7 can store the measured values in the form of battery data in a memory (not shown) of the BMS 2. The BMS 2 further has a communication unit (not shown) adapted to communicate the battery data. The battery data can be sent out for a predefined event. This predefined event can be a termination of the successful establishment of a communication connection with a network. In this case, the BMS 2 can retrieve the battery data stored in the memory and forward it to the network in packets via a mobile radio system. In the event of a handover, for example when the vehicle including the BMS 2 switches between two cells of the mobile radio system, the battery data can be stored in packets in such a way that a first part of the packets is transferred in the transferring cell and a second part of the packets is transferred in the service cell, so that the battery data consisting of the first and second part of the packets is ultimately combined in the network. A so-called arbiter 13 is shown in FIG. 1 as the destination of the battery data, which can, for example, act as a data administrator, intermediary or fleet manager. The decision as to whether a remote diagnosis is performed can be made by the arbiter 13.

The arbiter 13 receives the battery data in order to transmit it to the remote diagnostic unit 3. The arbiter 13 is adapted to transmit a request to the remote diagnostic unit 3 to evaluate the measured values included in the battery data for critical faults of the battery 4. In response to the request from the arbiter 13 to the remote diagnostic unit 3, the latter can transmit a request confirmation to the arbiter 13 in order to be able to receive the battery data. The arbiter 13 then transmits the battery data to the remote diagnostic unit.

It is also conceivable that the arbiter 13 can be omitted and the request is made directly by the BMS 2 instead of the arbiter 13.

If a critical error in the battery data is detected by the remote diagnostic unit 3, the arbiter 13 is informed accordingly, which performs corresponding measures in response, for example communication with the BMS 2 or the operator of the device belonging to the battery 4, for example the vehicle driver.

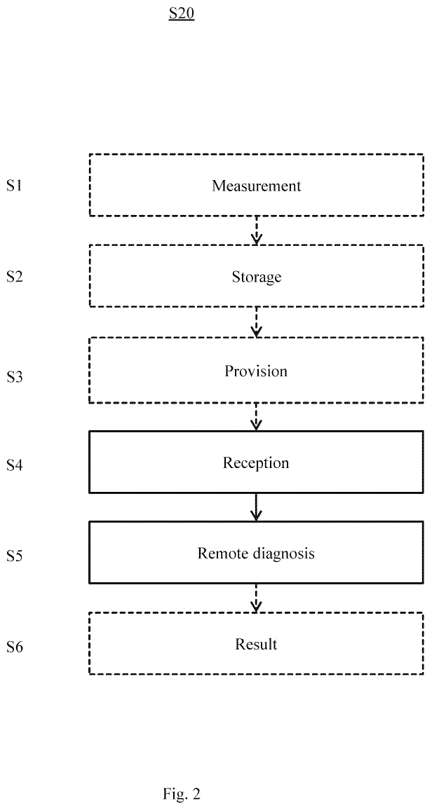

FIG. 2 outlines a method for the early detection of critical faults in a battery 4, with reference to FIG. 1. Steps S1, S2, S3 and S6 are carried out as described above with reference to FIG. 1. Thus, the measurement S1 is performed by the sensor control units 8, 9 on the battery cells 6, the battery modules 5, the battery 4 or the battery pack and stored by the main control unit 7 in a memory of the BMS 2. In a general manner, the first steps S1-S3 can also be performed by the BMS 2. The stored battery data is then provided in S3 to the remote diagnostic unit 3, for example by means of an arbiter 13. The battery data relates temporally to electrical characteristics of the battery cells 6, the battery modules 5, or the battery 4 or the battery pack measured during battery operation.

In S4, the battery data provided in S3 by the BMS 2 is received at the remote diagnostic unit 3. Afterwards, or simultaneously with the reception in S4, the remote diagnosis of the battery cells 6, the battery modules 5, or the battery 4 or the battery pack is performed in S5 by comparing the received battery data with reference battery data on a phase-by-phase and/or cycle-by-cycle basis. This comparison enables an effective quality check solely on the battery data or reference battery data in the corresponding phase-related or cycle-related time sections. The term “phase” as well as the term “cycle” can be understood here in a narrower sense, so that not several phases or not several cycles are meant. This means that the phase is either a charging phase, a transition phase or a discharging phase in relation to battery operation. It is further meant here that the cycle comprises each of the phases once, so that successive phases of the charging phase, the transition phase and the discharging phase are included exactly once.

In the result S6, the diagnostic results are transmitted, for example to the arbiter 13. Corresponding measures can thus be taken in S6, for example by means of the arbiter 13 as a monitoring or control organ. The end result of these measures can be, for example, the immobilization of the vehicle or the provision of information (trigger, warning, etc.) to the vehicle driver or the user of the device including the battery 4. The results can also be directly integrated by the remote diagnostic unit 3 communicating directly with the BMS 2, which in turn disconnects the battery 4, the corresponding faulty battery module 5 or the battery module 5 including the faulty battery cell 6. If disconnection is not technically possible, the entire battery pack can be removed, based on the information provided.

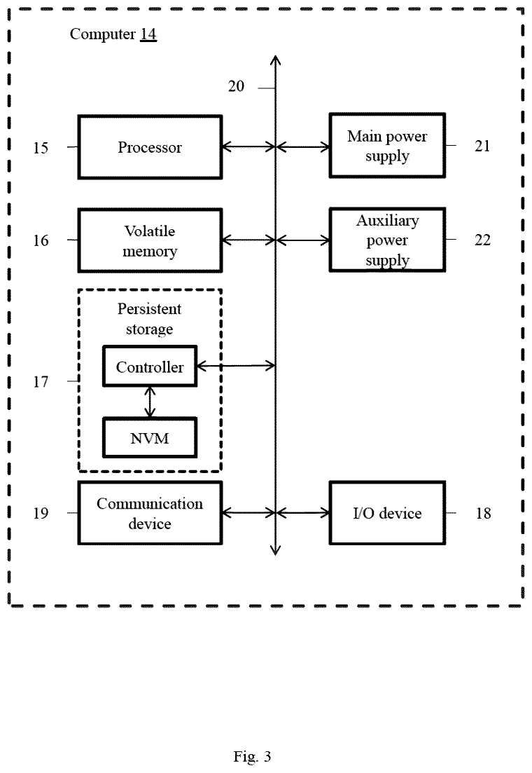

For example, the method steps depicted as blocks of the block diagram in FIG. 2 may be substantially mapped in a computer-readable medium and thus performed by a computer 14 or processor 15, such as described below with respect to FIG. 3, whether or not such a computer 14 or processor 15 is explicitly depicted in FIG. 2. Examples may further be or refer to a computer program that includes program code for performing at least part of the method steps when the computer program is performed on the computer 14 or processor 15. The computer 14 or processor 15 is programmed to perform the method steps thereby. An example may also have a non-volatile memory or persistent storage 17, such as also described below with respect to FIG. 3, which is machine-, processor- or computer-readable and encodes machine-executable, processor-executable or computer-executable programs with instructions. The instructions cause some or all of the process steps to be performed. Examples may also include dedicated (field) programmable logic arrays ((F) PLAs) or (field) programmable gate arrays ((F) PGAs) programmed to perform the procedural step(s).

FIG. 3 schematically shows a block diagram representing a computer 14. The computer 14 can, for example, describe the BMS 2 or the remote diagnostic unit 3, or part(s) thereof, suitable for the early detection of critical faults in a battery 4.

The computer 14 performs one or more steps of the method S20. For example, the computer 14 may implement some or all of the steps of the method S20 as represented in FIG. 2. In particular, the computer 14 provides functionality, such as computer software, that runs on the computer 14 and performs one or more steps of the method S20.

It is envisaged herein that the computer 14 may take any suitable physical form. By way of example, the computer 14 may be an embedded computer, system-on-chip (SOC), single board computer (SBC), cell phone, server, and/or tablet. The computer 14 may be unitary or distributed; span one or more locations; span one or more machines or data centers; or be located in a cloud, which may have cloud components in a network. The computer 14 may perform one or more steps of the method described or illustrated herein without significant spatial or temporal limitations. As an example, the computer 14 may perform one or more steps of the method S20 in real time, in parallel, or in batch mode. The computer 14 may perform step(s) of the method S20 at different times or locations.

The computer 14 has at least one or more of the following components: a processor 15, volatile memory 16, persistent storage 17 with controller and non-volatile memory (NVM) device, an input/output (I/O) device 18, communication device 19, a bus 20, a main power supply 21, and an auxiliary power supply 22. These components may be performed at least partially in hardware and/or software.

The processor 15 has means for performing instructions associated with the battery data, for example, a computer program. The processor 15 may have an internal register/cache for the battery data, for the instructions associated with the battery data, and/or for associated addresses. The processor 15 may have an arithmetic logic unit (ALU), logic circuit, field programmable logic gate array (FPGA), microprocessor, microcontroller, vector processor, processor integrated core, CPU (e.g., multi-core), coprocessor (microprocessor supporting the CPU), digital signal processor (DSP), graphics processing unit (GPU), and/or application specific integrated circuit (ASIC) for accessing the internal register/cache. As an example, to perform the instructions, the processor 15 may fetch the instructions from the internal register/cache of the processor 15, the volatile memory 16, or the persistent storage 17; decode and perform the instructions; and then write a result to the internal register/cache of the processor 15, the volatile memory 16, or the persistent storage 17. As an example, the processor 15 may have an instruction cache, a data cache, and/or a translation buffer (TLB). The instructions associated with the battery data in the instruction cache may be copies of instructions in the volatile memory 16 or persistent storage 17, and the instruction cache may accelerate fetching of these instructions associated with the battery data by the processor 15. The battery data in the data cache may be copies of data for battery data related instructions in the volatile memory 16 or persistent storage 17 currently being performed on the processor 15, for interacting with results of previous battery data related instructions being performed on the processor 15 for access by subsequent battery data related instructions to be performed on the processor 15, or for writing to the volatile memory 16 or persistent storage 17. The data cache may accelerate the read or write operations of the processor 15. The addresses associated with the battery data in the TLB may be address references to addresses in the volatile memory 16 or persistent storage 17 to accelerate virtual address translation for the processor 15.

The volatile memory 16 may be a dynamic RAM (DRAM) or a static RAM (SRAM). In particular, the volatile memory 16 may be adapted to be the computer readable medium described herein on which the computer program described herein may be stored. In addition, the volatile memory 16 may be a single or multi-channel RAM. The volatile memory 16 may have a main memory for storing instructions related to the battery data for the processor 15, which then performs those instructions; or the battery data for the processor 15 to use to operate on. As an example, the computer 14 may load these instructions into the volatile memory 16 from the persistent storage 17 or another source (such as another computer, the network, or the cloud). The processor 15 may then load these instructions from the volatile memory 16 into the internal register/cache of the processor 15. To perform these instructions, the processor 15 may fetch and decode these instructions from the corresponding internal register/cache. During or after performing these instructions, the processor 15 may write a result (which may be intermediate or final results) to the internal register/cache. The processor 15 may then write the result to the volatile memory 16.

For example, the processor 15 performs only the instructions related to the battery data in the internal register/cache of the processor 15 or in the volatile memory 16 (as opposed to the persistent storage 17), and operates only on the battery data in the internal register/cache of the processor 15 or in the volatile memory 16 (as opposed to the persistent storage 17). A memory management unit (MMU) may be located between the processor 15 and the volatile memory 16 and may support access requested by the processor 15 in connection with remote diagnosis to the volatile memory 16.

The bus 20 may have a memory bus. The memory bus (comprising an address bus and a data bus) may communicatively connect the processor 15 to the volatile memory 16. The bus 20 may be adapted to provide dedicated battery data communication between two or more of the internal components 15 to 22 of the computer 14. The bus 20 may have a ring topology, star topology, (partially) meshed topology, bus topology, tree topology and/or line topology. The bus 20 can be an Accelerated Graphics Port (AGP) or other graphics bus, Gunning Transceiver Logic (GTL) bus, Enhanced Industry Standard Architecture (EISA) bus, Front-Side-Bus (FSB), HYPERTRANSPORT (HT) bus, Industry Standard Architecture (ISA) bus, Low-Pin-Count (LPC) bus, Memory bus, Micro Channel Architecture (MCA) bus, Peripheral Component Interconnect (PCI) bus, PCI-Express (PCIe) bus, Serial Advanced Technology Attachment (SATA) bus, local Video Electronics Standards Association local (VLB) bus and/or have an INFINIBAND connection.

The persistent storage 17 has a mass memory, for example a non-volatile memory, for the battery data or the commands associated with the battery data. In particular, the persistent storage 17 may be adapted to be the computer-readable data carrier described herein, on which the computer program described herein may be stored. As an example, the persistent storage 17 may be a hard disk drive (HDD) or solid state drive (SSD), a flash memory, an optical disk, a magneto-optical disk, Secure Digital Memory Card (SD), Embedded Multi Media Card (eMMC) and/or a Universal Serial Bus (USB). The persistent storage 17 may have the battery data in an erasable or non-erasable manner. The persistent storage 17 may be located within the computer 14, i.e. internal, or external thereto. The persistent storage 17 may have a controller that supports communication for passing the battery data between the processor 15 and the persistent storage 17, in particular the non-volatile memory device NVM of the persistent storage 17.

The main power supply 21 supplies electrical power to at least one or more of the components 14 to 21. In particular, the main power supply 21 charges the auxiliary power supply 22 with electrical power, for example from outside the computer 14, in the case where the main power supply 21 is connected to a power source outside the computer 14.

The auxiliary power supply 22 is connected to the volatile memory 16 and/or the persistent storage 17 via the bus 20. The auxiliary power supply 22 is charged by the electrical power of the main power supply 21. The auxiliary power supply 22 may be arranged inside or outside the persistent storage 17. For example, the auxiliary power supply 22 may be accommodated on a motherboard of the computer 14 to provide auxiliary power to the volatile memory 16 and/or the persistent storage 17. In particular, the auxiliary power supply 22 may be performed in the form of a supercapacitor, an accumulator or a battery.

The processor 15 monitors changes in the electrical power supplied by the main power supply 21. In the event of a sudden power failure, such as when the power source external to the computer 14 is disconnected from the main power supply 21 or the main power supply 21 degrades or fails for another reason, and the processor determines that the electrical power supplied by the main power supply 21 to one or more of the components 14 to 21 has fallen below a threshold value, such as 0.8 or 0.75 of an operating power of the main power supply 21, the processor 15 causes the auxiliary power supply 22 to take over a remaining supply power for a shutdown operation of the computer 14. The shutdown operation comprises supplying power to at least the processor 15, the volatile memory 16 and the persistent storage 17 with electrical power for the time of the shutdown operation. During the shutdown process, the battery data that is currently in the volatile memory 16 and/or the battery data that is currently being processed in the processor 15, for example in the register/cache of the processor 15, is transferred from the volatile memory 16 and/or the processor 15 to a meta area of the persistent storage 17. For this purpose, the meta area of the persistent storage 17 can be kept separately for the shutdown process.

The processor 15 loads the battery data from the meta area of the persistent storage 17 in the event of a startup process of the computer 14, during which the main power supply 21 again provides the operating power, in order to enable faster data processing. After the startup process, the meta area of the persistent storage or successively during the startup process can be cleared.

The I/O device 18 may have the control units 7, 8, 9 or a portion thereof coupled to the processor 15 of the computer 14. The I/O device 18 may have a device and/or software driver that enables the processor 15 to control the I/O device 18 to obtain readings from the control units 7, 8, 9 or a portion thereof on which the battery data is based or represented by the battery data.

The communication device 19 provides a means for communicating (such as packet-based communication) the battery data between the computer 14 and other communication participants, such as to the network (wired or wireless) connected to the computer 14. As an example, the communication device 19 enables the computer 14 to communicate with an ad hoc network, a personal area network (PAN), a local area network (LAN), a wide area network (WAN), a metropolitan area network (MAN), and/or at least part of the Internet. As an example, the communication device 19 enables the computer 14 to communicate with a wireless PAN (WPAN; such as a BLUETOOTH WPAN), a WI-FI network, a WI-MAX network, and/or a cellular telephone network (e.g., GSM). In particular, the communication device 19 may have a transceiver, a receiver or a transmitter with one or more antennas. In one example, the processor 15 may include a baseband processor that performs modulation and/or demodulation, encoding and/or decoding of a baseband signal based on the battery data. In doing so, the communication device 19 converts the baseband signal from the processor 15 into a radio signal and transmits it via the antenna(s), and/or converts the radio signal received from the antenna(s) into the baseband signal and forwards it to the processor 15. The conversion may comprise an up/down conversion to/from a carrier frequency corresponding to the carrier wavelength λ. The transceiver, transmitter or receiver and the antenna(s) may be impedance matched with respect to each other with respect to the carrier frequency.

At this point, it should be noted that all the parts described above are claimed to be essential to the invention when viewed individually and in any combination, in particular the details shown in the drawings. Modifications thereof are familiar to the skilled person.

### REFERENCE NUMBER LIST

1 System
2 BMS
3 Remote diagnostic unit
4 Battery pack
5 Battery module
6 Battery cell
7 Main control unit
8 Sensor control unit
9 Sensor control unit
10 DC/DC converter
11 DC/AC converter
12 Motor
13 Arbiter
14 Computer
15 Processor
16 Volatile memory
17 Persistent storage
18 I/O device
19 Communication device
20 Bus
21 Main power supply
22 Auxiliary power supply

1. A method for early detection of critical faults of a battery (4, 5, 6), after commissioning and during a battery operation of the battery (4, 5, 6), the method comprising:
receiving (S4), at a remote diagnostic unit (3), battery data provided by a battery management system, BMS (2), associated with the battery (4, 5, 6), the battery data relating in time to electrical characteristics of the battery (4, 5, 6) measured during the battery operation; and
performing remote diagnosis (S5) of the battery (4, 5, 6) by comparing the received battery data with reference battery data phase by phase and/or cycle by cycle, wherein a phase is one of: a charging phase, a transition phase and a discharging phase related to the battery operation, and wherein a cycle comprises successive phases of the charging phase, the transition phase and the discharging phase.

2. The method according to claim 1, wherein the transition phase is between the charging phase and the discharging phase, the charging phase to another charging phase, the discharging phase to another discharging phase and/or from the discharging phase to the charging phase.

3. The method according to claim 1, wherein the reference battery data is battery data taken from a historical battery data set from a plurality of similar battery batches and/or battery data taken from a battery data set from the same battery batch.

4. The method according to claim 1, wherein
the method further comprises: extracting one or more functional profiles from the received battery data; and
performing the remote diagnosis further comprises: comparing the one or more functional profiles of the received battery data with corresponding one or more functional profiles of the reference battery data.

5. The method according to claim 4, wherein performing the remote diagnosis further comprises: triggering one or more indicators when one or more differences between the one or more functional profiles of the received battery data and the corresponding one or more functional profiles of the reference battery data exceed corresponding one or more predetermined thresholds.

6. The method according to claim 4, wherein the battery data or the one or more function profiles comprise at least one or more of the following information:
derivatives of a charge of the battery (4, 5, 6) with respect to a terminal voltage of the battery (4, 5, 6) according to the respective charging phases and discharging phases and/or derivatives of the terminal voltage of the battery (4, 5, 6) with respect to the charge of the battery (4, 5, 6) according to the respective charging phases and discharging phases;
charge throughputs and/or energy throughputs according to the respective charging and discharging phases;
internal resistances according to the respective transition phases;
electrical circuit models according to the respective transition phases and/or the electrical circuit models according to the respective charging phases and/or discharging phases; and
coulomb and/or energy and/or voltaic efficiencies and/or capacities or changes thereto according to the respective cycles.

7. The method according to claim 6, wherein, the remote diagnosis is performed as described below:
respectively comparing at least one maximum and/or at least one minimum of the derivatives with at least one maximum and/or at least one minimum of derivatives in the reference battery data and/or respectively comparing the derivatives with corresponding statistical upper and lower limit curves associated with the derivatives in the reference battery data;
respectively comparing the charge and/or energy throughputs with at least one first statistical boundary condition of the reference battery data;
comparing the internal resistances with at least one second statistical boundary condition of the reference battery data;
adapting parameters of the electrical circuit models to the battery data or the one or more functional profiles, and
respectively comparing the parameters of the electrical circuit models with corresponding parameters of an equivalent electrical circuit model of the reference battery data and/or
respectively comparing the parameters of the electrical circuit models with at least one third statistical boundary condition associated with the corresponding parameters of the reference battery data; and/or
comparing the coulomb and/or energy and/or voltaic efficiencies with at least one fourth statistical boundary condition of the reference battery data and/or capacities or changes thereto, and
comparing the capacities or changes thereto with at least one fifth statistical boundary condition of the reference battery data, and
wherein the at least one first, second, third, fourth and fifth boundary condition are independent of each other.

8. A computer program, wherein the computer program comprises instructions which, when the computer program is executed by a computer or by a battery management system, BMS, arbiter and/or remote diagnostic unit, cause the computer or the BMS, the arbiter and/or the remote diagnostic unit to perform the method or at least one of the steps of the method according to claim 1.

9. A computer-readable data carrier, wherein the computer program according to claim 8 is stored on the computer-readable data carrier.

10. A system (1) for early detection of critical faults of a battery (4, 5, 6), after commissioning and during a battery operation of the battery (4, 5, 6), the system (1) comprising:
a battery management system, BMS (2), associated with the battery (4, 5, 6), adapted to provide battery data relating in time to electrical characteristics of the battery (4, 5, 6) measured during the battery operation; and
a remote diagnosis unit (3) adapted to perform a remote diagnosis of the battery (4, 5, 6) by comparing the received battery data with reference battery data phase by phase and/or cycle by cycle, wherein a phase is one of: a charging phase, a transition phase and a discharging phase related to the battery operation, and wherein a cycle comprises successive phases of the charging phase, the transition phase and the discharging phase.
